(19) United States
(12) Patent Application Publication
(10) Pub. No.: US 2015/0181705 A1
(43) Pub. Date: Jun. 25, 2015

(54) BUILD-UP INSULATING FILM, PRINTED CIRCUIT BOARD INCLUDING EMBEDDED ELECTRONIC COMPONENT USING THE SAME AND METHOD FOR MANUFACTURING THE SAME

(71) Applicant: SAMSUNG ELECTRO-MECHANICS CO., LTD., Suwon-Si (KR)

(72) Inventor: Dae Seok SEO, Suwon-Si (KR)

(73) Assignee: SAMSUNG ELECTRO-MECHANICS CO., LTD., Suwon-Si (KR)

(21) Appl. No.: 14/326,706

(22) Filed: Jul. 9, 2014

(30) Foreign Application Priority Data
Dec. 24, 2013 (KR) 10-2013-0162881

(51) Int. Cl. H05K 1/03; H05K 3/00; B32B 27/36; H05K 1/18; C09J 7/02; H05K 3/30; H05K 13/04

(52) U.S. Cl. CPC H05K 1/0313; H05K 3/30; H05K 3/00; H05K 13/04; H05K 1/186; C09J 7/02; C09J 7/0282; B32B 27/36; H05K 2201/0209; C09J 2423/103; C09J 2467/006; B32B 2250/02; B32B 2255/00; B32B 2307/206; B32B 2457/08

(57) ABSTRACT

Disclosed herein are a build-up insulating film, a printed circuit board including an embedded electronic component using the same and a method for manufacturing the same.

The build-up insulating film according to the present invention includes: a build-up film layer; and an adhesion layer formed on the other surface of the build-up film layer, wherein the adhesion layer is formed by mixing at least one selected from epoxy-based, silicone-based, polyimide-based, urethane-based and ceramic-based materials.

### CROSS REFERENCE TO RELATED APPLICATION

This application claims the benefit of Korean Patent Application No. 10-2013-0162881, filed on Dec. 24, 2013, entitled “Build-up Insulating Film, Printed Circuit Board Including Embedded Electronic Component Using the Same and Method for Manufacturing the Same”, which is hereby incorporated by reference in its entirety into this application.

### BACKGROUND OF THE INVENTION

1. Technical Field

The present invention relates to a build-up insulating film, a printed circuit board including an embedded electronic component using the same and a method for manufacturing the same.

2. Description of the Related Art

In order to implement a printed circuit board including an embedded electronic component, there are many surface mounting technologies for mounting a semiconductor component such as an integrated circuit (IC) chip on a printed circuit board.

In addition, in order to manufacture a printed circuit board (PCB) having a thin thickness and high integration, a scheme in which various kinds of build-up insulating films are sequentially stacked and pressed has been used.

The build-up film has a significantly thin thickness, and both surfaces of the build-up insulating film are protected by covering them with predetermined protective films for protection against external circumstances.

Therefore, the build-up insulating film is prepared and carried in a state in which both surfaces thereof are covered with predetermined protective films.

Then, during a process for manufacturing a printed circuit board, the protective films are separated from the build-up substrate and the build-up insulating film is merely selectively used.

### PRIOR ART DOCUMENT

### Patent Document

(Patent Document 1) US Patent Application Publication No. 2008-0115349

### SUMMARY OF THE INVENTION

The present invention has been made in an effort to provide a build-up film having high peel strength.

In addition, the present invention has been made in an effort to provide a build-up film improving mechanical, thermal, and electrical properties of a printed circuit board including an embedded electronic component.

Further, the present invention has been made in an effort to provide a printed circuit board including an embedded electronic component capable of easily disposing an electronic component at the time of embedding the electronic component in a cavity of a substrate and simplifying a manufacturing process, and a method for manufacturing the same.

In addition, a printed circuit board including an embedded electronic component capable of forming a thin printed circuit board including an embedded electronic component without warpage generation, and a method for manufacturing the same.

According to a preferred embodiment of the present invention, there is provided a build-up insulating film including: a build-up film layer; and an adhesion layer formed on the other surface of the build-up film layer, wherein the adhesion layer is formed by mixing at least one selected from epoxy-based, silicone-based, polyimide-based, urethane-based and ceramic-based materials.

The build-up insulating film may further include a base film layer protecting the build-up film layer.

The base film layer may be made of polyethyelene terepthalate (PET).

The build-up insulating film may further include a cover film layer protecting the adhesion layer.

The cover film layer may be made of oriented polypropylene film (OPP).

The adhesion layer may have a cross section thickness of 0.1 to 10 μm.

The build-up film layer may be formed by mixing at least one selected from a bisphenol A type epoxy resin, a cresol novolac epoxy resin, a rubber modified epoxy resin and a phosphorus-based epoxy resin.

According to another preferred embodiment of the present invention, there is provided a printed circuit board including an embedded electronic component, including: a substrate having circuit patterns and cavity formed thereon; an electronic component embedded in the cavity of the substrate; and a build-up insulating film and an insulating film layer covering both surfaces of the substrate and the electronic component, respectively; wherein the build-up insulating film includes a build-up film layer; and an adhesion layer formed on the other surface of the build-up film layer, and the adhesion layer is formed by mixing at least one selected from epoxy-based, silicone-based, polyimide-based, urethane-based and ceramic-based materials.

One surface of the substrate and the electronic component may be adhered to the adhesion layer of the build-up insulating film.

The substrate may be made of a composition containing a photosensitive monomer and a photoinitiator.

The substrate may contain a resin composition containing a composite epoxy resin including a naphthalene-based epoxy resin and a rubber modified epoxy resin, a curing agent, a curing accelerator, and an inorganic filler.

The adhesion layer may have a cross section thickness of 0.1 to 10 μm.

The build-up film layer may be formed by mixing at least one selected from a bisphenol A type epoxy resin, a cresol novolac epoxy resin, a rubber modified epoxy resin and a phosphorus-based epoxy resin.

According to another preferred embodiment of the present invention, there is provided a method for manufacturing a printed circuit board including an embedded electronic component, the method including: forming a cavity in a substrate having circuit patterns formed thereon so that an electronic component is embedded in the substrate; preparing a build-up insulating film to be adhered to one surface of the substrate; adhering the build-up insulating film to one surface of the substrate so that a portion of an adhesion layer is exposed by the cavity of the substrate; and adhering the electronic component on the adhesion layer exposed by the cavity, wherein the build-up insulating film includes a build-up film layer; and an adhesion layer formed on the other surface of the build-up film layer, and the adhesion layer is formed by mixing at least one selected from epoxy-based, silicone-based, polyimide-based, urethane-based and ceramic-based materials.

The substrate may be made of a composition containing a photosensitive monomer and a photoinitiator.

The substrate may contain a resin composition containing a composite epoxy resin including a naphthalene-based epoxy resin and a rubber modified epoxy resin, a curing agent, a curing accelerator, and an inorganic filler.

In the adhering of the build-up insulating film, a portion of the adhesion layer may be exposed by the cavity of the substrate, and one surface of the build-up film layer may be exposed.

The method may further include, after the adhering of the electronic component, stacking an insulating film layer on a surface facing the build-up insulating film so as to cover the substrate having one exposed surface and the electronic component.

The method may further include, after the stacking of the insulating film layer, collectively curing the build-up insulating film and the insulating film layer.

The cavity may be formed by a laser processing.

The cavity may be formed by exposing and developing processes.

The adhesion layer may have a cross section thickness of 0.1 to 10 μm.

The build-up film layer may be formed by mixing at least one selected from a bisphenol A type epoxy resin, a cresol novolac epoxy resin, a rubber modified epoxy resin and a phosphorus-based epoxy resin.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view schematically showing a structure of a build-up insulating film according to a preferred embodiment of the present invention;

FIG. 2 is a cross-sectional view schematically showing a structure of a printed circuit board including an embedded electronic component according to a preferred embodiment of the present invention; and

FIGS. 3 to 7 are cross-section views sequentially showing a process for manufacturing the printed circuit board including the embedded electronic component according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Build-Up Insulating Film

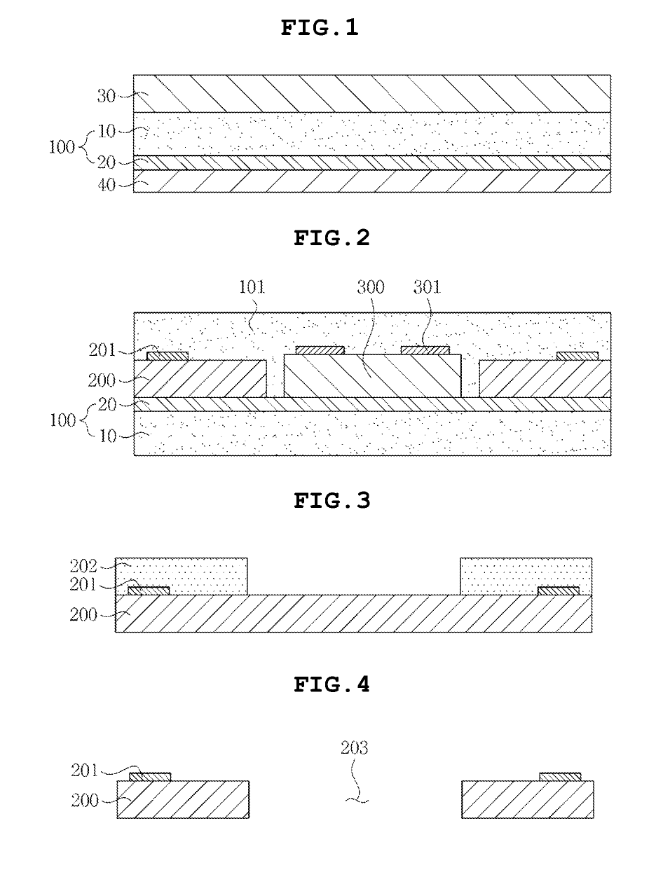

FIG. 1 is a cross-sectional view schematically showing a structure of a build-up insulating film according to a preferred embodiment of the present invention.

Referring to FIG. 1, a build-up insulating film 100 includes: a build-up film layer 10; and an adhesion layer 20 formed on the other surface of the build-up film layer 10, wherein the adhesion layer 20 is formed by mixing at least one selected from epoxy-based, silicone-based, polyimide-based, urethane-based and ceramic-based materials.

The build-up film layer 10 may be formed by mixing at least one selected from a bisphenol A type epoxy resin, a cresol novolac epoxy resin, a rubber modified epoxy resin and a phosphorus-based epoxy resin.

A composite epoxy resin composition containing at least one of the above-described resins is used and may contain an additive, a curing agent, and a curing accelerator.

As the additive, a flame retardant aid may be further contained.

The flame retardant aid may be used in order to decrease a content of flame retardant epoxy resin which is relatively expensive.

As the flame retardant aid, a compound such as Al₂O₃ containing phosphorus may be used.

The curing agent may contain at least any one of phenol novolac and bisphenol novolac. As an example of the curing agent, a bisphenol A novolac (BPA novolac) epoxy resin curing agent may be used.

As a method for forming circuit layers (not shown) on the build-up film layer 10 which is an insulating material, various methods already known in the art may be used, and a detailed description thereof will be omitted.

In order to form the circuit layer (not shown), any material may be applied without limitation as long as a material is used as a conductive metal, and is typically made of copper in the case of a printed circuit board.

In addition, the build-up insulating film may further include a base film 30 layer protecting the build-up film layer 10, and the base film 30 may be made of polyethyelene terepthalate (PET).

The adhesion layer 20 may be formed by mixing at least one selected from epoxy-based, silicone-based, polyimide-based, urethane-based and ceramic-based materials, and may be mixed with an additive capable of improving adhesion strength with a substrate 200.

In order to increase a chemical bonding affinity with the build-up film layer 10 which is the composite epoxy resin composition, a surface may be treated with a silane-coupling agent.

As the silane-coupling agent, amino-based, epoxy-based, acrylic-based, vinyl-based materials, and the like, may be used.

In addition, various kinds of inorganic fillers may be contained.

For example, a metal oxide powder containing at least any one of a layered silicate, talc, aluminum, magnesium, zinc, calcium, strontium, zirconium, barium, tin, neodymium, bismuth, lithium, samarium and tantalum may be used.

The adhesion layer 20 may have a cross section thickness of 0.1 to 10 μm and has adhesion strength of 0.5 g/cm or more when adhering to the electronic component 300 and the substrate 200 at room temperature.

In addition, adhesion strength after a final curing process is performed is 0.3 kg/cm or more.

Further, the build-up insulating film may further include a cover film layer 40 protecting the adhesion layer 20 and the cover film layer 40 may be made of oriented polypropylene film (OPP).

In the case of applying the build-up insulating film 100 to a printed circuit board including an embedded electronic component, peel strength between the build-up insulating film 100 having the adhesion layer 20 formed thereon and the circuit patterns 201 of the substrate 200 may be improved to improve mechanical, thermal, and electrical properties.

Further, since a taping process for attaching or detaching a tape supporting electronic component 300 is not necessary, the manufacturing process may be simplified, such that time and cost may be reduced.

Printed Circuit Board Including Embedded Electronic Component

FIG. 2 is a cross-sectional view schematically showing a structure of a printed circuit board including an embedded electronic component according to a preferred embodiment of the present invention.

Referring to FIG. 2, a printed circuit board including an embedded electronic component according to a preferred embodiment of the present invention may include: a substrate 200 having circuit patterns 201 and cavity 203 formed thereon; an electronic component 300 embedded in the cavity 203 of the substrate 200; and a build-up insulating film 100 and an insulating film layer 101 covering both surfaces of the substrate 200 and the electronic component 300, respectively; wherein the build-up insulating film 100 includes a build-up film layer 10; and an adhesion layer 20 formed on the other surface of the build-up film layer 10, and the adhesion layer 20 is formed by mixing at least one selected from epoxy-based, silicone-based, polyimide-based, urethane-based and ceramic-based materials.

The substrate 200 may be made of a composition containing a photosensitive monomer and a photoinitiator. In addition, the substrate may contain a resin composition containing a composite epoxy resin including a naphthalene-based epoxy resin and a rubber modified epoxy resin, a curing agent, a curing accelerator, and an inorganic filler.

The cavity 203 formed in order to embed the electronic component 300 in the substrate 200 may be formed by a photolithography process.

In the present invention, a material of the substrate 200 is not limited thereto, and may be the same as already known in the art.

In general, the substrate 200 may contain a thermosetting resin such as an epoxy resin, a thermoplastic resin such as polyimide, polyethyelene terepthalate (PET), or a resin containing a reinforcing agent such as a glass fiber or an inorganic filler impregnated thereto, for example, a prepreg, and may contain a thermosetting resin and/or a photocurable resin, and the like. However, the present invention is not particularly limited thereto.

The substrate 200 has copper clad layers having patterns formed thereon on both surfaces thereof, and may be referred to as a connection pad, a circuit pattern 201 and/or a circuit layer.

In a preferred embodiment of the present invention, the copper clad layer is referred to as a circuit pattern 201, and a material of the circuit pattern may be applied without limitation as long as a material is used as a conductive metal, and is typically made of copper in the case of a printed circuit board.

Although one layered substrate 200 is shown in the drawings, the substrate is a circuit substrate having one and more layered circuits formed thereon, preferably, a printed circuit board.

It may be easily appreciated by a person skilled in the art that a general multilayer printed circuit board having one and more layered circuits formed on the insulation layer may be used as a substrate 200.

The cavity 203 formed in order to embed the electronic component 300 in the substrate 200 may be formed by a laser processing, wherein the laser processing may be preferably and mainly performed using a CO₂ laser, but may be performed by at least one kind of carbon dioxide (CO₂), YAG and Eximer, and the present invention is not limited to a kind of laser.

Here, the electronic component 300 embedded in the substrate 200 is a component electrically connecting to a printed circuit board to perform a predetermined function, and for example, an electronic component 300 which is capable of being embedded in a printed circuit board together with a integrated circuit (IC) chip.

Although other detailed components including a connection pad 301 of the electronic component 300 are omitted and the drawings are schematically shown, it may be easily appreciated by a person skilled in the art that all electronic components 300 having structures known in the art are not particularly limited, but may be applied to the printed circuit board including an embedded electronic component 300 according to the present invention.

Both of the build-up insulating film 100 and the insulating film layer 101 covering both surfaces of the substrate 200 and the electronic component 300, respectively, as described above are insulating films in a B-stage state.

Here, the build-up insulating film 100 adhered to one surface of the substrate 200 and the electronic component 300 includes: a build-up film layer 10; and an adhesion layer 20 formed on the other surface of the build-up film layer 10, wherein the adhesion layer 20 is formed by mixing at least one selected from epoxy-based, silicone-based, polyimide-based, urethane-based and ceramic-based materials.

The build-up film layer 10 may be formed by mixing at least one selected from a bisphenol A type epoxy resin, a cresol novolac epoxy resin, a rubber modified epoxy resin and a phosphorus-based epoxy resin.

A composite epoxy resin composition containing at least one of the above-described resins is used and may contain an additive, a curing agent, and a curing accelerator.

As an additive, a flame retardant aid may be further contained.

The flame retardant aid may be used in order to decrease a content of flame retardant epoxy resin which is relatively expensive.

As the flame retardant aid, a compound such as Al₂O₃ containing phosphorus may be used.

The curing agent may contain at least any one of phenol novolac and bisphenol novolac. As an example of the curing agent, a bisphenol A novolac (BPA novolac) epoxy resin curing agent may be used.

As a method for forming circuit layers (not-shown) on the build-up film layer 10 which is an insulating material, various methods already known in the art may be used, and a detailed description thereof will be omitted.

In order to form the circuit layer (not shown), any material may be applied without limitation as long as a material is used as a conductive metal, and is typically made of copper in the case of a printed circuit board.

The adhesion layer 20 may be formed by mixing at least one selected from epoxy-based, silicone-based, polyimide-based, urethane-based and ceramic-based materials, and may be mixed with an additive capable of improving adhesion strength with a substrate 200.

In order to increase a chemical bonding affinity with the build-up film layer 10 which is the composite epoxy resin composition, a surface may be treated with a silane-coupling agent.

As the silane-coupling agent, amino-based, epoxy-based, acrylic-based, vinyl-based materials, and the like, may be used.

In addition, various kinds of inorganic fillers may be contained. For example, a metal oxide powder containing at least any one of a layered silicate, talc, aluminum, magnesium, zinc, calcium, strontium, zirconium, barium, tin, neodymium, bismuth, lithium, samarium and tantalum may be used.

The adhesion layer 20 may have a cross section thickness of 0.1 to 10 μm and has adhesion strength of 0.5 g/cm or more when adhering to the electronic component 300 and the substrate 200 at room temperature.

In addition, adhesion strength after a final curing process is performed is 0.3 kg/cm or more.

One surface of the substrate 200 and the electronic component 300 as described above is adhered to the adhesion layer 20 of the build-up insulating film 100.

The substrate 200 and the electronic component 300 tightly fixed and adhered to the adhesion layer 20 is not easily moved, such that mechanical, thermal, and electrical properties may be excellent. Therefore, the build-up insulating film 100 having the adhesion layer 20 formed thereon is used, such that reliability of a product may be improved.

The insulating film layer 101 stacked on a surface facing the build-up insulating film 100 is made of the same component as the previously described build-up film layer 10 of the build-up insulating film 100, and may be prepared by mixing at least one selected from a bisphenol A type epoxy resin, a cresol novolac epoxy resin a rubber modified epoxy resin and a phosphorus-based epoxy resin.

A composite expoxy resin composition containing at least one of the above-described resins is used and may contain an additive, a curing agent, and a curing accelerator.

As an additive, a flame retardant aid may be further contained.

The flame retardant aid may be used in order to decrease a content of flame retardant epoxy resin which is relatively expensive.

As the flame retardant aid, a compound such as Al₂O₃ containing phosphorus may be used.

The curing agent may contain at least any one of phenol novolac and bisphenol novolac. As an example of the curing agent, a bisphenol A novolac (BPA novolac) epoxy resin curing agent may be used.

The printed circuit board including an embedded electronic component using the build-up insulating film 100 according to the present invention may include the adhesion layer 20 having high peel strength in the build-up insulating film, such that the build-up insulating film 100 may have high close adhesion strength between the substrate 200 and the electronic component 300, whereby product reliability of the printed circuit board including an embedded electronic component may be improved.

Method for Manufacturing Printed Circuit Board Including Embedded Electronic Component

FIGS. 3 to 7 are cross-section views sequentially showing a process for manufacturing the printed circuit board including the embedded electronic component according to a preferred embodiment of the present invention.

First, referring to FIGS. 3 and 4, a substrate 200 having circuit patterns 201 formed thereon is prepared and a cavity 203 is formed so that an electronic component 300 is embedded in the substrate 200.

The substrate 200 may be made of a composition containing a photosensitive monomer and a photoinitiator. In addition, the substrate may contain a resin composition containing a composite epoxy resin including a naphthalene-based epoxy resin and a rubber modified epoxy resin, a curing agent, a curing accelerator, and an inorganic filler. However, the present invention is not limited thereto.

The cavity 203 formed in order to embed the electronic component 300 in the substrate 200 may be formed by a photolithography process.

In this case, a resist layer may be selectively formed on the substrate 200.

Here, the resist layer 202 may be a photosensitive resist.

As the photosensitive resist, a dry film or positive liquid photo resist (L-LPR) may be used.

The film, which is mainly used for forming circuits of the printed circuit board, may include a positive film and a negative film.

After developing the resist layer 202, the substrate 200 may be exposed by a predetermined light such as ultraviolet ray, X-ray, an electron beam, or the like, and may be developed by an alkali developing solution, thereby removing a non-exposed part.

In the present invention, a material of the substrate 200 is not limited thereto, and the substrate may be formed by technology already known in the art.

For example, the substrate 200 may contain a thermosetting resin such as an epoxy resin, a thermoplastic resin such as polyimide, polyethyelene terepthalate (PET), or a resin containing a reinforcing agent such as a glass fiber or an inorganic filler impregnated thereto, for example, a prepreg, and may contain a thermosetting resin and/or a photocurable resin, and the like. However, the present invention is not particularly limited thereto.

Here, the cavity 203 formed in order to embed the electronic component 300 in the substrate 200 may be formed by a laser processing, wherein the laser processing may be preferably and mainly performed using a CO₂ laser, but may be performed by at least one kind of carbon dioxide (CO₂), YAG and Eximer, and the present invention is not limited to a kind of laser.

The substrate 200 has copper clad layers having patterns formed thereon on both surfaces thereof, and may be referred to as a connection pad, a circuit pattern 201 and/or a circuit layer.

In a preferred embodiment of the present invention, the copper clad layer is referred to as a circuit pattern 201, and a material of the circuit pattern may be applied without limitation as long as a material is used as a conductive metal, and is typically made of copper in the case of a printed circuit board.

Although one layered substrate 200 is shown in the drawings, the substrate is a circuit substrate having one or more layered circuits formed thereon, preferably, a printed circuit board.

It may be easily appreciated by a person skilled in the art that a general mutilayer printed circuit board having one and more layered circuits formed on the insulation layer may be used as a substrate.

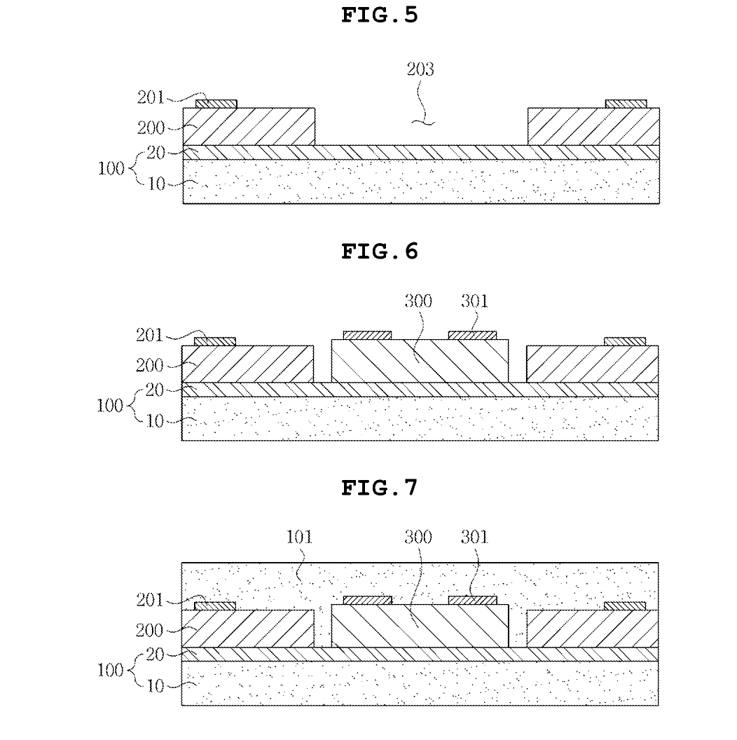

Then, referring to FIG. 5, the build-up insulating film 100 adhered to one surface of the substrate 200 having the cavity 203 formed therein is prepared and an adhesion layer 20 of the build-up insulating film 100 is adhered to one surface of the substrate 200.

Here, a portion of the adhesion layer 20 of the build-up insulating film 100 is exposed by the cavity 203 of the substrate 200.

The build-up insulating film 100 includes: a build-up film layer 10; and an adhesion layer 20 formed on the other surface of the build-up film layer 10, wherein the adhesion layer 20 is formed by mixing at least one selected from epoxy-based, silicone-based, polyimide-based, urethane-based and ceramic-based materials.

The build-up film layer 10 may be formed by mixing at least one selected from a bisphenol A type epoxy resin, a cresol novolac epoxy resin, a rubber modified epoxy resin and a phosphorus-based epoxy resin.

A composite expoxy resin composition containing at least one of the above-described resins is used and may contain an additive, a curing agent, and a curing accelerator.

As an additive, a flame retardant aid may be further contained.

The flame retardant aid may be used in order to decrease a content of flame retardant epoxy resin which is relatively expensive.

As the flame retardant aid, a compound such as Al₂O₃ containing phosphorus may be used.

The curing agent may contain at least any one of phenol novolac and bisphenol novolac. As an example of the curing agent, a bisphenol A novolac (BPA novolac) epoxy resin curing agent may be used.

As a method for forming circuit layers (not-shown) on the build-up film layer 10 which is an insulating material, various methods already known in the art may be used, and a detailed description thereof will be omitted.

In order to form the circuit layer (not shown), any material may be applied without limitation as long as a material is used as a conductive metal, and is typically made of copper in the case of a printed circuit board.

The adhesion layer 20 may be formed by mixing at least one selected from epoxy-based, silicone-based, polyimide-based, urethane-based and ceramic-based materials, and may be mixed with an additive capable of improving adhesion strength with a substrate 200.

In order to increase a chemical bonding affinity with the build-up film layer 10 which is the composite epoxy resin composition, a surface may be treated with a silane-coupling agent.

As the silane-coupling agent, amino-based, epoxy-based, acrylic-based, vinyl-based materials, and the like, may be used.

In addition, various kinds of inorganic fillers may be contained. For example, a metal oxide powder containing at least any one of a layered silicate, talc, aluminum, magnesium, zinc, calcium, strontium, zirconium, barium, tin, neodymium, bismuth, lithium, samarium, tantalum may be used.

The adhesion layer 20 may have a cross section thickness of 0.1 to 10 μm and has adhesion strength of 0.5 g/cm or more when adhering to the electronic component 300 and the substrate 200 at room temperature.

In addition, adhesion strength after a final curing process is performed is 0.3 kg/cm or more.

Then, referring to FIG. 6, the electronic component 300 is embedded on the adhesion layer 20 of the build-up insulating film 100 exposed in the cavity of the substrate 200.

Here, the electronic component 300 embedded in the substrate 200 is a component electrically connecting to a printed circuit board to perform a predetermined function, and for example, an electronic component 300 which is capable of being embedded in a printed circuit board together with a integrated circuit (IC) chip.

Although other detailed components including a connection pad 301 of the electronic component 300 are omitted and the drawings are schematically shown, it may be appreciated by a person skilled in the art that all electronic components 300 having structures known in the art are not particularly limited, but may be applied to the printed circuit board including an embedded electronic component 300 according to the present invention.

Then, referring to FIG. 7, the insulating film layer 101 is stacked on a surface facing the build-up insulating film 100.

Here, the insulating film layer 101 is adhered to an opposite surface of the substrate 200 having one surface adhered by the build-up insulating film 100, and the build-up film layer 10 and the substrate 200 of the build-up insulating film 100 may contain materials in a B-stage state or materials having the same state as B-stage.

The insulating film layer 101 stacked on a surface facing the build-up insulating film 100 is made of the same component as the previously described build-up film layer 10 of the build-up insulating film 100, and may be prepared by mixing at least one selected from a bisphenol A type epoxy resin, a cresol novolac epoxy resin, a rubber modified epoxy resin and a phosphorus-based epoxy resin.

A composite expoxy resin composition containing at least one of the above-described resins is used and may contain an additive, a curing agent, and a curing accelerator.

As an additive, a flame retardant aid may be further contained.

The flame retardant aid may be used in order to decrease a content of flame retardant epoxy resin which is relatively expensive.

As the flame retardant aid, a compound such as Al₂O₃ containing phosphorus may be used.

The curing agent may contain at least any one of phenol novolac and bisphenol novolac. As an example of the curing agent, a bisphenol A novolac (BPA novolac) epoxy resin curing agent may be used.

After stacking the insulating film layer 101 described above, collectively curing the build-up insulating film 100 and the insulating film layer 101 may be further included.

Cracks including warpage generation of the substrate 200 which is generated at the time of separately curing an upper surface and a lower surface may be prevented by collectively curing the build-up insulating film and the insulating film layer.

In addition, the build-up insulating film and the insulating film layer is collectively cured after the electronic component 300 is tightly fixed and adhered to the adhesion layer 20 of the build-up insulating film 100, such that the substrate 200 and the electronic component 300 are not easily moved.

Therefore, mechanical, thermal, and electrical properties of a product may be improved, such that with the printed circuit board using the build-up insulating film 100 having the adhesion layer 20 formed thereon and the method for manufacturing the same, reliability of a product may be improved.

With the build-up insulating film according to the preferred embodiment of the present invention and the printed circuit board including an embedded electronic component using the same, the adhesion layer having high peel strength is included in the build-up insulating film, such that the build-up insulating film may have high close adhesion strength between the substrate and the electronic component, whereby reliability of a product may be improved.

In addition, peel strength between the build-up insulating film and the circuit patterns of the substrate may be improved, such that mechanical, thermal, and electrical properties may be improved.

Further, since the taping process for attaching or detaching the tape supporting the electronic component is not necessary, the manufacturing process may be simplified, such that time and cost may be reduced.

Further, cracks including warpage generation of the substrate may be prevented by collectively curing the uncured build-up insulating film and the insulating film layer.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A build-up insulating film comprising:
a build-up film layer; and
an adhesion layer formed on the other surface of the build-up film layer,
wherein the adhesion layer is formed by mixing at least one selected from epoxy-based, silicone-based, polyimide-based, urethane-based and ceramic-based materials.

2. The build-up insulating film as set forth in claim 1, further comprising a base film layer protecting the build-up film layer.

3. The build-up insulating film as set forth in claim 2, wherein the base film layer is made of polyethyelene terepthalate (PET).

4. The build-up insulating film as set forth in claim 1, further comprising a cover film layer protecting the adhesion layer.

5. The build-up insulating film as set forth in claim 4, wherein the cover film layer is made of oriented polypropylene film (OPP).

6. The build-up insulating film as set forth in claim 1, wherein the adhesion layer has a cross section thickness of 0.1 to 10 μm.

7. The build-up insulating film as set forth in claim 1, wherein the build-up film layer is formed by mixing at least one selected from a bisphenol A type epoxy resin, a cresol novolac epoxy resin, a rubber modified epoxy resin and a phosphorus-based epoxy resin.

8. A printed circuit board including an embedded electronic component, comprising:
a substrate having circuit patterns and cavity formed thereon;
an electronic component embedded in the cavity of the substrate; and
a build-up insulating film and an insulating film layer covering both surfaces of the substrate and the electronic component, respectively;
wherein the build-up insulating film includes a build-up film layer; and an adhesion layer formed on the other surface of the build-up film layer, and the adhesion layer is formed by mixing at least one selected from epoxy-based, silicone-based, polyimide-based, urethane-based and ceramic-based materials.

9. The printed circuit board as set forth in claim 8, wherein one surface of the substrate and the electronic component is adhered to the adhesion layer of the build-up insulating film.

10. The printed circuit board as set forth in claim 8, wherein the substrate is made of a composition containing a photosensitive monomer and a photoinitiator.

11. The printed circuit board as set forth in claim 8, wherein the substrate contains a resin composition containing a composite epoxy resin including a naphthalene-based epoxy resin and a rubber modified epoxy resin, a curing agent, a curing accelerator, and an inorganic filler.

12. The printed circuit board as set forth in claim 8, wherein the adhesion layer has a cross section thickness of 0.1 to 10 μm.

13. The printed circuit board as set forth in claim 8, wherein the build-up film layer is formed by mixing at least one selected from a bisphenol A type epoxy resin, a cresol novolac epoxy resin, a rubber modified epoxy resin and a phosphorus-based epoxy resin.

14. A method for manufacturing a printed circuit board including an embedded electronic component, the method comprising:
forming a cavity in a substrate having circuit patterns formed thereon so that an electronic component is embedded in the substrate;
preparing a build-up insulating film to be adhered to one surface of the substrate;
adhering the build-up insulating film to one surface of the substrate so that a portion of an adhesion layer is exposed by the cavity of the substrate; and
adhering the electronic component on the adhesion layer exposed by the cavity,
wherein the build-up insulating film includes a build-up film layer; and an adhesion layer formed on the other surface of the build-up film layer, and the adhesion layer is formed by mixing at least one selected from epoxy-based, silicone-based, polyimide-based, urethane-based and ceramic-based materials.

15. The method as set forth in claim 14, wherein the substrate is made of a composition containing a photosensitive monomer and a photoinitiator.

16. The method as set forth in claim 14, wherein the substrate contains a resin composition containing a composite epoxy resin including a naphthalene-based epoxy resin and a rubber modified epoxy resin, a curing agent, a curing accelerator, and an inorganic filler.

17. The method as set forth in claim 14, wherein in the adhering of the build-up insulating film, a portion of the adhesion layer is exposed by the cavity of the substrate, and one surface of the build-up film layer is exposed.

18. The method as set forth in claim 14, further comprising, after the adhering of the electronic component, stacking an insulating film layer on a surface facing the build-up insulating film so as to cover the substrate having one exposed surface and the electronic component.

19. The method as set forth in claim 18, further comprising, after the stacking of the insulating film layer, collectively curing the build-up insulating film and the insulating film layer.

20. The method as set forth in claim 14, wherein the cavity is formed by a laser processing.

21. The method as set forth in claim 14, wherein the cavity is formed by exposing and developing processes.

22. The method as set forth in claim 14, wherein the adhesion layer has a cross section thickness of 0.1 to 10 μm.

23. The method as set forth in claim 14, wherein the build-up film layer is formed by mixing at least one selected from a bisphenol A type epoxy resin, a cresol novolac epoxy resin, a rubber modified epoxy resin and a phosphorus-based epoxy resin.
